(19) United States
(12) Patent Application Publication
(10) Pub. No.: US 2024/0079468 A1
(43) Pub. Date: Mar. 7, 2024

(54) VERTICAL TRANSISTOR AND MANUFACTURING METHOD THEREOF

(71) Applicant: Samsung Electronics Co., Ltd., Suwon-si (KR)

(72) Inventors: Moonil JUNG, Suwon-si (KR); Sangwook KIM, Suwon-si (KR); Euntae KIM, Suwon-si (KR); Jeeeun YANG, Suwon-si (KR); Kwanghee LEE, Suwon-si (KR)

(73) Assignee: Samsung Electronics Co., Ltd., Suwon-si (KR)

(21) Appl. No.: 18/457,803

(22) Filed: Aug. 29, 2023

(30) Foreign Application Priority Data
Sep. 2, 2022 (KR) 10-2022-0111679

(51) Int. Cl. H01L 29/45; H01L 29/66; H01L 29/786

(52) U.S. Cl. CPC H01L 29/45; H01L 29/66969; H01L 29/78606; H01L 29/78642; H01L 29/7869; H01L 21/02491; H01L 29/78696

(57) ABSTRACT

Provided are a vertical transistor and a method of manufacturing the same. The vertical transistor includes a substrate, a lower electrode on the substrate and including a metal material, a carbon thin film being conductive and on the lower electrode, an oxide semiconductor layer on the carbon thin film, a gate electrode apart from the oxide semiconductor layer, a gate insulating layer arranged between the oxide semiconductor layer and the gate electrode, and an upper electrode on the oxide semiconductor layer, wherein the lower electrode. The carbon thin film, the oxide semiconductor layer, and the upper electrode are arranged in a direction perpendicular to the substrate.

### CROSS-REFERENCE TO RELATED APPLICATION

This application is based on and claims priority under 35 U.S.C. § 119 to Korean Patent Application No. 10-2022-0111679, filed on Sep. 2, 2022, in the Korean Intellectual Property Office, the disclosure of which is incorporated by reference herein in its entirety.

### BACKGROUND

Various example embodiments to a vertical transistor including an oxide semiconductor layer as a channel layer, and/or a method of manufacturing the vertical transistor.

An oxide semiconductor device is or includes a transparent semiconductor device having a wide band gap greater than or equal to about 3.0 eV. Research on such device has been conducted for years.

An oxide semiconductor device may be used in a memory or a logic device and manufactured through a low-temperature process performed at a temperature less than or equal to about 500° C. The oxide semiconductor device may also be used in a display driving device.

### SUMMARY

Provided is a vertical transistor with improved electrical characteristics.

Alternatively or additionally, provided is a method of manufacturing a vertical transistor.

Additional aspects will be set forth in part in the description which follows and, in part, will be apparent from the description, or may be learned by practice of example embodiments.

According to various example embodiments, a vertical transistor includes a substrate, a lower electrode on the substrate and including a metal material, a conductive carbon thin film on the lower electrode, an oxide semiconductor layer on the carbon thin film, a gate electrode apart from the oxide semiconductor layer, a gate insulating layer between the oxide semiconductor layer and the gate electrode, and an upper electrode on the oxide semiconductor layer. The lower electrode, the carbon thin film, the oxide semiconductor layer, and the upper electrode are arranged in a direction perpendicular to the substrate.

The gate insulating layer may entirely surround side surfaces of the oxide semiconductor layer.

The lower electrode, the carbon thin film, the oxide semiconductor layer, and the upper electrode may be sequentially stacked without any intervening layer.

The lower electrode may have a width greater than or equal to a width of the oxide semiconductor layer.

The vertical transistor may further include a mold insulating layer on the lower electrode and defining an opening, and the carbon thin film may be on a bottom portion of the opening.

The oxide semiconductor layer may include a first vertical extension on a first sidewall of the opening, a second vertical extension on a second sidewall of the opening, and a lower portion connected between the first vertical extension and the second vertical extension.

The gate electrode may extend in a second horizontal direction and may include a first gate electrode corresponding to the first vertical extension and a second gate electrode corresponding to the second vertical extension, and the gate insulating layer may include a first gate insulating layer corresponding to the first gate electrode and a second gate insulating layer corresponding to the second gate electrode.

The gate electrode may include a first gate electrode and a second gate electrode that face each other and are configured to be driven electrically independently, and the gate insulating layer may include a first gate insulating layer corresponding to the first gate electrode and a second gate insulating layer corresponding to the second gate electrode.

The oxide semiconductor layer may have a U-shaped structure.

The lower electrode may include at least one metal selected from among tungsten (W), cobalt (Co), nickel (Ni), iron (Fe), titanium (Ti), molybdenum (Mo), chromium (Cr), zirconium (Zr), hafnium (Hf), niobium (Nb), tantalum (Ta), silver (Ag), gold (Au), aluminum (Al), copper (Cu), tin (Sn), vanadium (V), ruthenium (Ru), platinum (Pt), zinc (Zn), and magnesium (Mg).

The carbon thin film may include at least one of graphene, fullerene, and a carbon nanotube.

The oxide semiconductor layer may include at least one selected from among InGaZnO, ZnO, ZrInZnO, InZnO, ZnO, InGaZnO₄, ZnInO, ZnSnO, In₂O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, TiSrO₃, ZIO, IGO, and combinations thereof.

According to various example embodiments, a method of manufacturing a vertical transistor includes arranging a lower electrode on a substrate, depositing a carbon thin film on the lower electrode, the carbon thin film being conductive, depositing an oxide semiconductor layer on the carbon thin film, depositing a gate insulating layer on the oxide semiconductor layer, depositing a gate electrode on the gate insulating layer, depositing an upper electrode on the oxide semiconductor layer. The depositing of the oxide semiconductor layer includes adsorbing a precursor onto the carbon thin film, and enabling a reactor to react with the precursor.

The lower electrode, the carbon thin film, the oxide semiconductor layer, and the upper electrode may be arranged in a direction perpendicular to the substrate.

The enabling the reactor may include activating a reactor by plasma.

The depositing of the oxide semiconductor layer may further include providing a first purge gas before the adsorbing of the precursor onto the carbon thin film and after the enabling of the reactor to react with the precursor, and providing a second purge gas after the enabling of the reactor to react with the precursor.

The method further includes depositing a mold insulating layer on the lower electrode with an opening, and the carbon thin film may be arranged on a bottom portion of the opening.

### BRIEF DESCRIPTION OF THE DRAWINGS

The above and other aspects, features, and advantages of certain example embodiments will be more apparent from the following description taken in conjunction with the accompanying drawings, in which:

FIG. 1 illustrates a vertical transistor according to various embodiments;

FIG. 2 illustrates a vertical transistor according to some example embodiments;

FIG. 3 illustrates a vertical transistor according to some example embodiments;

FIG. 4 illustrates a vertical transistor according to some example embodiments;

FIG. 5 illustrates a method of manufacturing a vertical transistor according to some example embodiments;

FIG. 6 is a graph showing contact characteristics according to a channel-layer stack structure in a top-contact transistor including a metal electrode arranged on a channel layer;

FIG. 7 is an on-current graph for comparing contact characteristics according to a channel-layer stack structure in a bottom-contact transistor including a metal electrode arranged under a channel layer;

FIG. 8 is a graph showing contact characteristics according to a channel-layer stack structure in a bottom-contact transistor including a metal electrode arranged under a channel layer;

FIGS. 9A and 9B are graphs showing a reduction in metal (tungsten) electrode oxide generation according to the existence of a carbon (graphene) thin film in a bottom-contact transistor in which a metal electrode is arranged under a channel layer;

FIG. 10 is a diagram for explaining an operation of stacking a mold insulating layer on a lower electrode in a method of manufacturing a vertical transistor, according to various example embodiments;

FIG. 11 is a diagram for explaining an operation of stacking a carbon thin film on a lower electrode in a method of manufacturing a vertical transistor, according to various example embodiments;

FIG. 12 is a diagram for explaining an operation of stacking an oxide semiconductor layer in a method of manufacturing a vertical transistor, according to various example embodiments;

FIG. 13 is a diagram for explaining an operation of stacking a gate insulating layer in a method of manufacturing a vertical transistor, according to various example embodiments;

FIG. 14 is a diagram for explaining an operation of stacking a gate electrode in a method of manufacturing a vertical transistor, according to various example embodiments;

FIG. 15 is a diagram for explaining an etching operation in a method of manufacturing a vertical transistor, according to various example embodiments;

FIG. 16 is a diagram for explaining an operation of forming an insulating liner, a buried insulating layer, and an upper insulating layer in a method of manufacturing a vertical transistor, according to various example embodiments;

FIG. 17 is a diagram for explaining an operation of forming an upper electrode in a method of manufacturing a vertical transistor, according to various example embodiments;

FIG. 18 is a diagram for explaining an operation of forming an upper electrode insulating layer in a method of manufacturing a vertical transistor, according to various example embodiments;

FIG. 19 is a diagram for explaining an etching operation in a method of manufacturing a vertical transistor, according to various example embodiments;

FIG. 20 is a diagram for explaining an operation of forming an insulating liner, a buried insulating layer, and an upper insulating layer in a method of manufacturing a vertical transistor, according to various example embodiments;

FIG. 21 is a diagram for explaining an operation of forming an upper electrode in a method of manufacturing a vertical transistor, according to various example embodiments; and

FIG. 22 is a diagram for explaining an operation of forming an upper electrode insulating layer in a method of manufacturing a vertical transistor, according to various example embodiments.

### DETAILED DESCRIPTION

Reference will now be made in detail to various embodiments, examples of which are illustrated in the accompanying drawings, wherein like reference numerals refer to like elements throughout. In this regard, the present embodiments may have different forms and should not be construed as being limited to the descriptions set forth herein. Accordingly, some example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, vertical transistors and/or methods of manufacturing the same according to various example embodiments are described in detail with reference to the attached drawings. Like reference numerals in the drawings denote like elements, and sizes of components in the drawings may be exaggerated for convenience of explanation. It will be understood that although the terms “first,” “second,” etc. may be used herein to describe various components, these components should not be limited by these terms. The terms are only used to distinguish one component from another.

As used herein, the singular forms “a,” “an,” and “the” are intended to include the plural forms as well, unless the context clearly indicates otherwise. It will be further understood that the terms “comprises” and/or “comprising” used herein specify the presence of stated features or components, but do not preclude the presence or addition of one or more other features or components. Also, sizes or thicknesses of components in the drawings may be exaggerated for clarity.

As used herein, the singular forms “a,” “an,” and “the” are intended to include the plural forms as well, unless the context clearly indicates otherwise.

Operations of all methods described herein may be performed in any suitable order unless otherwise indicated herein or otherwise clearly contradicted by context. The use of any and all examples language (e.g., “such as”) provided herein, is intended merely to better illuminate the disclosure and does not pose a limitation on the scope unless otherwise claimed.

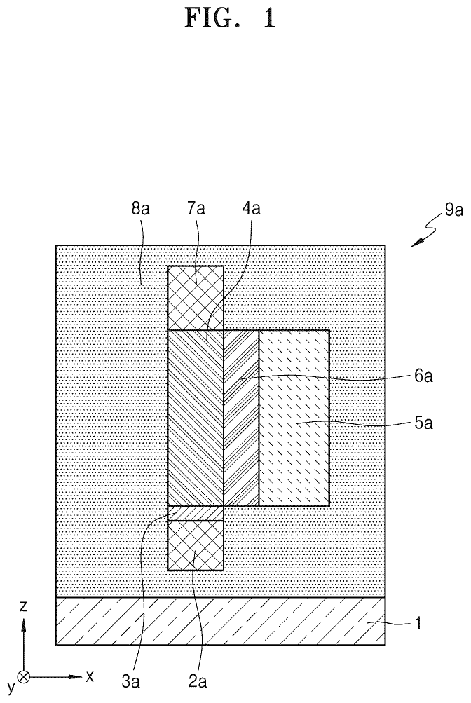

FIG. 1 illustrates a vertical transistor according to various example embodiments.

Referring to FIG. 1, a vertical transistor 9a may include a substrate 1, a lower electrode 2a, a carbon thin film 3a, an oxide semiconductor layer 4a, and an upper electrode 7a.

The substrate 1 may have a flat shape extending along a plane. A vertical direction z may be a direction perpendicular to the substrate 1. For example, the substrate 1 may include a conductive substrate. The substrate 1 may include a semiconductor substrate such as but not limited to a silicon substrate; however, example embodiments are not limited thereto. The substrate 1 may be doped with impurities; however, example embodiments are not limited thereto.

The lower electrode 2a may be arranged above the substrate 1. The lower electrode 2a may be arranged above an upper portion of the substrate 1 and lower than the oxide semiconductor layer 4a. The lower electrode 2a may be located in the vertical direction z of the substrate 1. The oxide semiconductor layer 4a may function as a channel layer. The lower electrode 2a may include a metal material. The lower electrode 2a may include at least one selected from the group consisting of tungsten (W), cobalt (Co), nickel (Ni), iron (Fe), titanium (Ti), molybdenum (Mo), chromium (Cr), zirconium (Zr), hafnium (Hf), niobium (Nb), tantalum (Ta), silver (Ag), gold (Au), aluminum (Al), copper (Cu), tin (Sn), vanadium (V), ruthenium (Ru), platinum (Pt), zinc (Zn), and magnesium (Mg). The lower electrode 2a may or may not directly contact the substrate 1, but although the lower electrode 2a does not directly contact the substrate 1, the lower electrode 2a may be electrically connected to the substrate 1. For example, there may be a conductive path (not illustrated) between the lower electrode 2a and the substrate 1. The lower electrode 2a may be, function as, or serve as a source or a drain of the vertical transistor 9a; however, example embodiments are not limited thereto.

The carbon thin film 3a may be located on an upper surface of the lower electrode 2a. The carbon thin film 3a may be located in a vertical direction z of the lower electrode 2a. The carbon thin film 3a may include a conductive material. The carbon thin film 3a may include one or more of graphene, fullerene, and a carbon nanotube. The carbon thin film 3a may entirely cover the upper surface of the lower electrode 2a. For example, a width of the carbon thin film 3a may be the same as or greater than a width of the lower electrode 2a. A thickness of the carbon thin film 3a may be about 0.3 nm to about 5 nm. The thickness of the carbon thin film 3a may be about 1 nm to about 2 nm. The carbon thin film 3a may include three or more layers. For example, when the carbon thin film 3a includes graphene, a thickness of a tri-layer of the carbon thin film 3a may be about 1 nm.

The carbon thin film 3a may be arranged between the lower electrode 2a and the oxide semiconductor layer 4a and may be, serve as, or function as an interface. The carbon thin film 3a may be configured to improve contact characteristics with the lower electrode 2a and the oxide semiconductor layer 4a, and may help to reduce the formation of a Schottky diode between the lower electrode 2a and the oxide semiconductor layer 4a. The improvement in the contact characteristics may include improvement in electrical characteristics. The electrical characteristic improvement may include ohmic contact formation. The carbon thin film 3a may decrease a contact resistance. When the contact resistance is low, a contact size may decrease when the vertical transistor 9a is designed. The decrease in the contact size may enable or help to enable high integration of the vertical transistor 9a.

Alternatively or additionally the carbon thin film 3a may prevent or reduce the likelihood of and/or impact from materials working as detects from being generated and diffusing. The carbon thin film 3a may function as a diffusion barrier or partial diffusion barrier. For example, the carbon thin film 3a may prevent or reduce hydrogen and/or metal oxide diffusing through the lower electrode 2a and thus improve thermal reliability and bias reliability. When the carbon thin film 3a blocks or at least partially blocks hydrogen, a negative shift of a threshold voltage of the oxide semiconductor layer 4a such as a negative bias temperature instability (NBTI) may be prevented or reduced in likelihood of occurrence.

The oxide semiconductor layer 4a may be arranged on the carbon thin film 3a. The oxide semiconductor layer 4a may contact or directly contact an upper surface of the carbon thin film 3a. The oxide semiconductor layer 4a may be located in a vertical direction z of the carbon thin film 3a. The oxide semiconductor layer 4a may entirely cover the upper surface of the carbon thin film 3a. For example, a width of the oxide semiconductor layer 4a may be the same as or greater than that of the carbon thin film 3a. The oxide semiconductor layer 4a may extend in a direction in which the substrate 1, the lower electrode 2a, and the carbon thin film 3a are sequentially stacked in a stated order. The oxide semiconductor layer 4a may be deposited according to an Atomic Layer Deposition (ALD) method; however, example embodiments are not limited thereto. In some example embodiments, the oxide semiconductor layer 4a may be deposited according to a Plasma Enhanced Atomic Layer Deposition (PEALD) method. The oxide semiconductor layer 4a may include a material selected from the among or from the group consisting of InGaZnO, ZnO, ZrInZnO, InZnO, ZnO, InGaZnO₄, ZnInO, ZnSnO, In₂O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, TiSrO₃, ZIO, IGO, and combinations thereof. The oxide semiconductor layer 4a may function as a channel layer and may have a band gap greater than or equal to about 3.0 eV.

A gate electrode 5a may be arranged apart from the oxide semiconductor layer 4a. The gate electrode 5a may face some or all portions of the oxide semiconductor layer 4a. The gate electrode 5a may include an electrically conductive material. For example, the gate electrode 5a may include metal and/or metal oxide. In this case, the gate insulating layer 6a may be arranged between the oxide semiconductor layer 4a and the gate electrode 5a and electrically disconnect the oxide semiconductor layer 4a from the gate electrode 5a. The gate insulating layer 6a may include an insulating material. For example, the gate insulating layer 6a may include a dielectric. A width of the gate insulating layer 6a may be the same as or greater than that of the gate electrode 5a.

The upper electrode 7a may be arranged on the oxide semiconductor layer 4a. The upper electrode 7a may include a metal material. The upper electrode 7a may be arranged on the oxide semiconductor layer 4a in a direction in which the lower electrode 2a, the carbon thin film 3a, and the oxide semiconductor layer 4a are sequentially stacked. The upper electrode 7a may be located in a vertical direction z of the oxide semiconductor layer 4a. The lower electrode 2a, the carbon thin film 3a, the oxide semiconductor layer 4a, and the upper electrode 7a may be sequentially stacked in a direction (a z direction) perpendicular to the substrate 1 without any intervening layer therebetween. The upper electrode 7a may be or function as a source electrode and/or a drain electrode; example embodiments are not limited thereto.

A mold insulating layer 8a may fill an empty space so that the lower electrode 2a, the carbon thin film 3a, the oxide semiconductor layer 4a, the upper electrode 7a, the gate electrode 5a, and the gate insulating layer 6a are fixed on the substrate 1. The mold insulating layer 8a may include an insulating material.

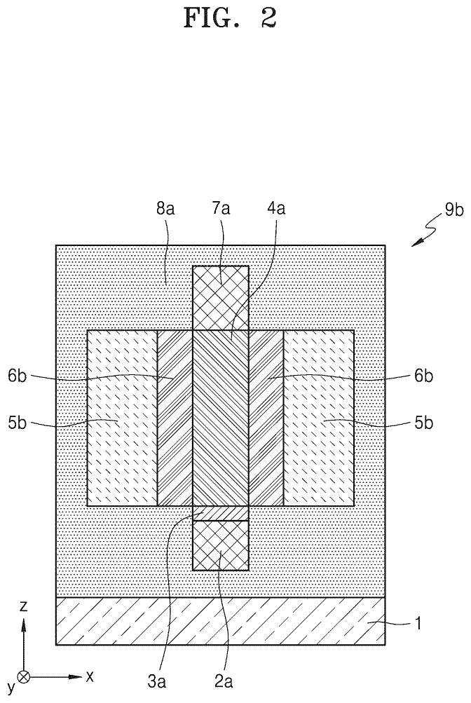

FIG. 2 illustrates a vertical transistor according to some example embodiments.

Hereinafter, the descriptions regarding components using the same reference numerals as the components in FIG. 1 are omitted, and differences therebetween are mainly described.

Referring to FIG. 2, a vertical transistor 9b may include the substrate 1, the lower electrode 2a, the carbon thin film 3a, the oxide semiconductor layer 4a, a gate electrode 5b, a gate insulating layer 6b, and the upper electrode 7a.

The vertical transistor 9b may have a gate-all-around structure in which the gate electrode 5b surrounds the oxide semiconductor layer 4a. The gate insulating layer 6b may be arranged between the oxide semiconductor layer 4a and the gate electrode 5b. When the gate electrode 5b entirely surrounds the oxide semiconductor layer 4a, a leakage current may be controlled.

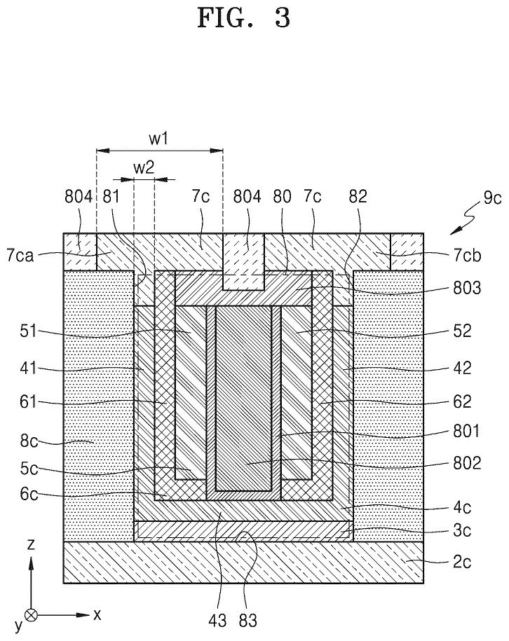

FIG. 3 illustrates a vertical transistor according to some example embodiments.

Hereinafter, the repeated descriptions are omitted, and differences are mainly described.

Referring to FIG. 3, a vertical transistor 9c may include a lower electrode 2c, a carbon thin film 3c, an oxide semiconductor layer 4c, a gate electrode 5c, a gate insulating layer 6c, an upper electrode 7c, and a mold insulating layer 8c.

A first horizontal direction x may be perpendicular to the vertical direction z. On the substrate 1, the lower electrode 2c extending in the first horizontal direction x may be disposed. The lower electrode 2c may be connected to a plurality of transistors (not shown). The lower electrode 2c may be a bit line BL. The lower electrode 2c may have a width greater than or equal to that of the oxide semiconductor layer 4c.

A single or a plurality of mold insulating layers 8c may be arranged on the lower electrode 2c. The mold insulating layer 8c may include an insulator. A second horizontal direction y may be perpendicular to both the vertical direction z and the first horizontal direction x. The mold insulating layer 8c may extend in the second horizontal direction y. The mold insulating layer 8c may have a certain height in the vertical direction z. An opening 80 formed by the plurality of mold insulating layers 8c and the lower electrode 2c may be arranged or defined. The opening 80 may be a trench when viewed in the second horizontal direction y. The opening 80 may be provided in plural. On an upper surface of the lower electrode 2c, a bottom portion 83 of the opening 80 may be located. The opening 80 may include a first sidewall 81 and a second sidewall 82. With respect to the first horizontal direction x on the right side, a left sidewall of the opening 80 may be the first sidewall 81, and a right sidewall thereof may be the second sidewall 82.

The carbon thin film 3c may be arranged on the lower electrode 2c. The carbon thin film 3c may be arranged on the bottom portion 83 of the opening 80.

The oxide semiconductor layer 4c may be arranged on the carbon thin film 3c. The oxide semiconductor layer 4c may include a first vertical extension 41, a second vertical extension 42, and a lower portion 43. The first vertical extension 41 may be located on the first sidewall 81 of the opening 80. The second vertical extension 42 may be located on the second sidewall 82 of the opening 80. The lower portion 43 may connect the first vertical extension 41 to the second vertical extension 42. The lower portion 43 may contact the carbon thin film 3c. The oxide semiconductor layer 4c may have a U-shaped cross-section. The oxide semiconductor layer 4c may have sharp inner and/or outer corners, or may have beveled or rounded inner and/or outer corners.

The gate electrode 5c may be formed apart from the oxide semiconductor layer 4c. The gate electrode 5c may extend in the second horizontal direction y. The gate electrode 5c may be a word line WL. The gate electrode 5c may include a first gate electrode 51 and a second gate electrode 52. The first gate electrode 51 and the second gate electrode 52 may be formed apart from each other. An electrical signal to the first gate electrode 51 may not be identical to an electrical signal to the second gate electrode 52. The first gate electrode 51 may control a channel of the first vertical extension 41 of the oxide semiconductor layer 4c, and independently the second gate electrode 52 may control a channel of the second vertical extension 42.

The gate insulating layer 6c may be arranged between the gate electrode 5c and the oxide semiconductor layer 4c. The gate insulating layer 6c may include an insulating material. The gate insulating layer 6c may include a first gate insulating layer 61 and a second gate insulating layer 62. The first gate insulating layer 61 may be arranged between the first vertical extension 41 of the oxide semiconductor layer 4c and the first gate electrode 51. The second gate insulating layer 62 may be arranged between the second vertical extension 42 of the oxide semiconductor layer 4c and the second gate electrode 52.

An insulating liner 801 may be arranged between the first gate electrode 51 and the second gate electrode 52 that are spaced apart from each other. A buried insulating layer 802 may fill a gap between the first gate electrode 51 and the second gate electrode 52 that are spaced apart from each other on the insulating liner 801. The insulating liner 801 may be conformally arranged on sidewalls of the first gate electrode 51 and the second gate electrode 52, which face each other, and on an upper surface of the lower portion 43 of the oxide semiconductor layer 4c. The insulating liner 801 may have an upper surface located on the same plane as the gate electrode 5c. For example, the insulating liner 801 may include silicon nitride and may or may not include silicon oxide, and the buried insulating layer 802 may include silicon oxide and may or may not include silicon nitride. In the opening 80 formed by the mold insulating layer 8c, an upper insulating layer 803 may be arranged on the gate electrode 5c and the buried insulating layer 802. An upper surface of the upper insulating layer 803 may be at the same level as an upper surface of the mold insulating layer 8c.

The upper electrode 7c may be arranged on the oxide semiconductor layer 4c. The upper electrode 7c may function as a landing pad. The upper electrode 7c may include a left upper electrode 7ca and a right upper electrode 7cb. The left upper electrode 7ca may be electrically connected to the first vertical extension 41 of the oxide semiconductor layer 4c. The right upper electrode 7cb may be electrically connected to the second vertical extension 42. The left upper electrode 7ca may not be electrically connected to the right upper electrode 7cb. The upper electrode 7c may include an upper portion and a lower portion. The upper portion of the upper electrode 7c may be a portion of the upper electrode 7c that is at a higher level than the upper surface of the mold insulating layer 8c. The lower portion of the upper electrode 7c may be a portion of the upper electrode 7c that is arranged inside upper electrode recesses defined between the mold insulating layer 8c and the upper insulating layer 803. In some embodiments, the upper portion of the upper electrode 7c may have a first width w1 in the first horizontal direction x, and the lower portion of the upper electrode 7c may have a second width w2 less than the first width w1 in the first horizontal direction x. The lower portion of the upper electrode 7c may be arranged inside the upper electrode recess, the upper portion of the upper electrode 7c may have, on the lower portion of the upper electrode 7c, a bottom surface arranged on the upper surface of the mold insulating layer 8c and the upper insulating layer 803, and thus, the upper electrode 7c may have a T-shaped vertical cross-section. The bottom surface of the lower portion of the upper electrode 7c may contact the upper surface of the oxide semiconductor layer 4c. Both sidewalls of the lower portion of the upper electrode 7c may be aligned with both sidewalls of the first vertical extension 41 and the second vertical extension 42 that form the oxide semiconductor layer 4c. The bottom surface of the lower portion of the upper electrode 7c may be arranged at a higher level than an upper surface of the gate electrode 5c, and part of a sidewall of the lower portion of the upper electrode 7c may be covered by the gate insulating layer 6c. An upper electrode insulating layer 804 surrounding the periphery of the upper electrode 7c may be arranged on the mold insulating layer 8c and the upper insulating layer 803.

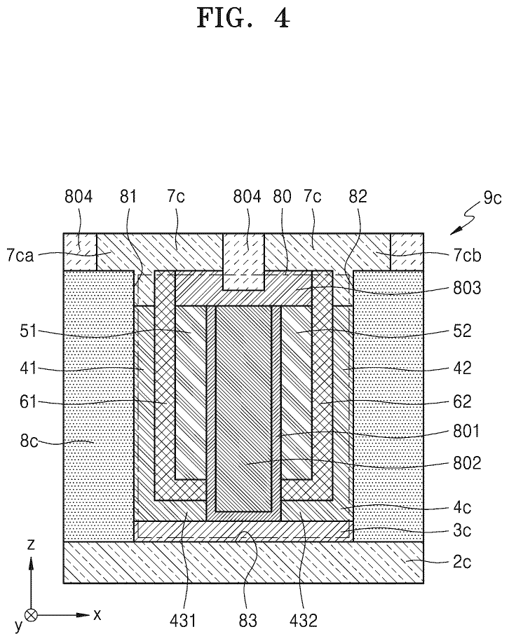

FIG. 4 illustrates a vertical transistor according to various example embodiments.

The descriptions already provided with reference to FIG. 3 are omitted in FIG. 4, and differences therebetween are mainly described.

Referring to FIG. 4, the oxide semiconductor layer 4c may include the first vertical extension 41, the second vertical extension 42, a lower left portion 431, and a lower right portion 432. The first vertical extension 41 may not be electrically connected to the second vertical extension 42.

The insulating liner 801 and the buried insulating layer 802 may electrically insulate the first vertical extension 41 and the second vertical extension 42 of the oxide semiconductor layer 4c from each other. The insulating liner 801 and the buried insulating layer 802 may cover a portion of an upper surface of the carbon thin film 3c.

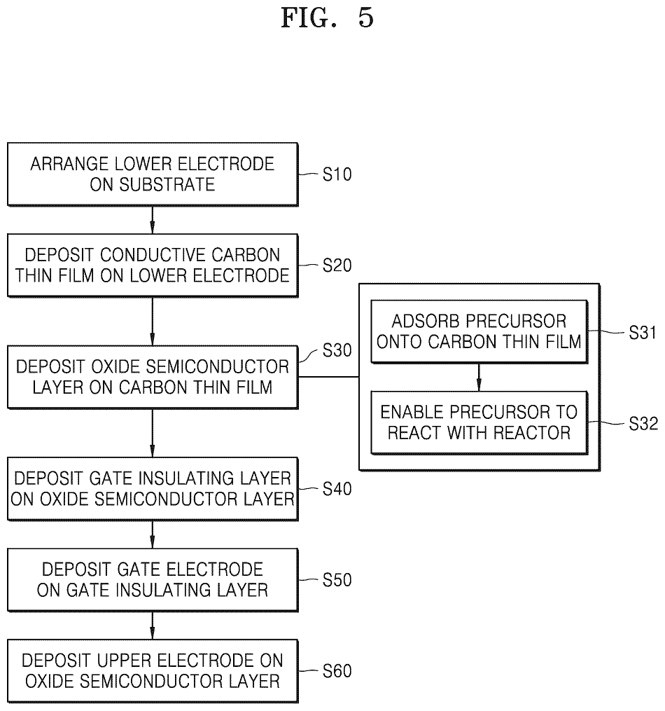

FIG. 5 illustrates a method of manufacturing a vertical transistor, according to various example embodiments. The method is described with reference to FIG. 1 illustrating an example of the vertical transistor.

Referring to FIGS. 1 and 5, the method of manufacturing a vertical transistor may include: arranging or provisioning or depositing the lower electrode 2a on the substrate 1 in operation S10; depositing the carbon thin film 3a, which is a conductive carbon film, on the lower electrode 2a in operation S20; depositing the oxide semiconductor layer 4a on the carbon thin film 3a in operation S30; depositing the gate insulating layer 6a on the oxide semiconductor layer 4a in operation S40; depositing the gate electrode 5a on the gate insulating layer 6a in operation S50; and depositing the upper electrode 7a on the oxide semiconductor layer 4a in operation S60.

Operation S30 of depositing the oxide semiconductor layer 4a on the carbon thin film 3a may include one or more of a sputtering process, an ALD process, or a PEALD process. Operation S30 of depositing the oxide semiconductor layer 4a may include operation S31 in which a precursor is adsorbed onto the carbon thin film 3a and operation S32 in which a reactor reacts with the precursor. Operation S30 of depositing the oxide semiconductor layer 4a may further include providing a first purge gas after operation S31, in which the precursor is adsorbed onto the carbon thin film 3a, and before operation S32 in which the reactor reacts with the precursor. After operation S32, in which the reactor reacts with the precursor, operation of providing a second purge gas may be further included. After operation S32, in which the reactor reacts with the precursor, operation S31, in which the precursor is adsorbed onto the carbon thin films 3a and 3c, is recurrent. Operation S31, in which the precursor is adsorbed onto the carbon thin films 3a and 3c, and operation S32, in which the reactor reacts with the precursor, may be repeatedly performed when the oxide semiconductor layers 4a and 4c are deposited on the carbon thin films 3a and 3c at desired thicknesses. Operation S31, in which the precursor is adsorbed onto the carbon thin films 3a and 3c, and operation S32, in which the reactor reacts with the precursor, may be repeatedly performed when the oxide semiconductor layer 4c is deposited on the carbon thin film 3c and the mold insulating layer 8c at a desired thickness.

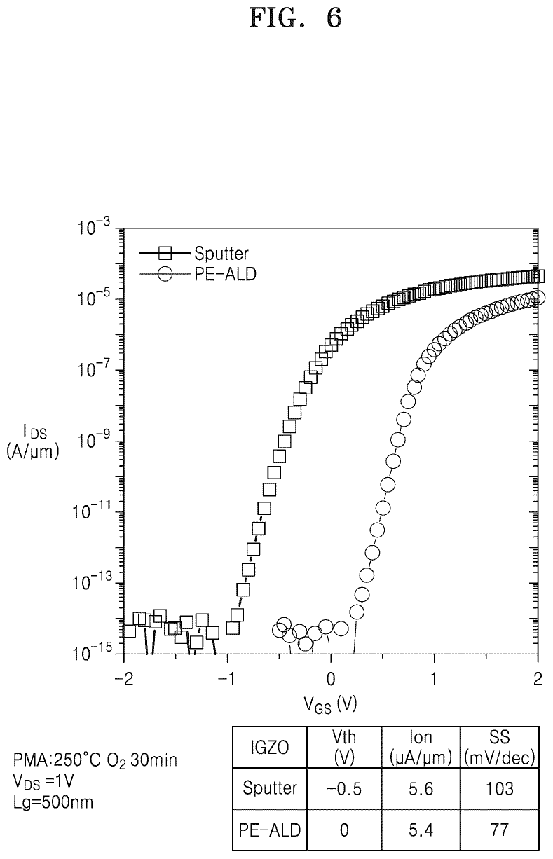

FIG. 6 is a graph showing contact and current-voltage (IV) characteristics according to a channel-layer stack structure in a top-contact transistor in which a metal electrode is arranged on a channel layer.

In the top-contact structure, when an oxide semiconductor layer is deposited according to a sputtering method, an on-current may be about 5.6 uA/um, and when the oxide semiconductor layer is deposited according to a PEALD method, the on-current may be about 5.4 uA/um.

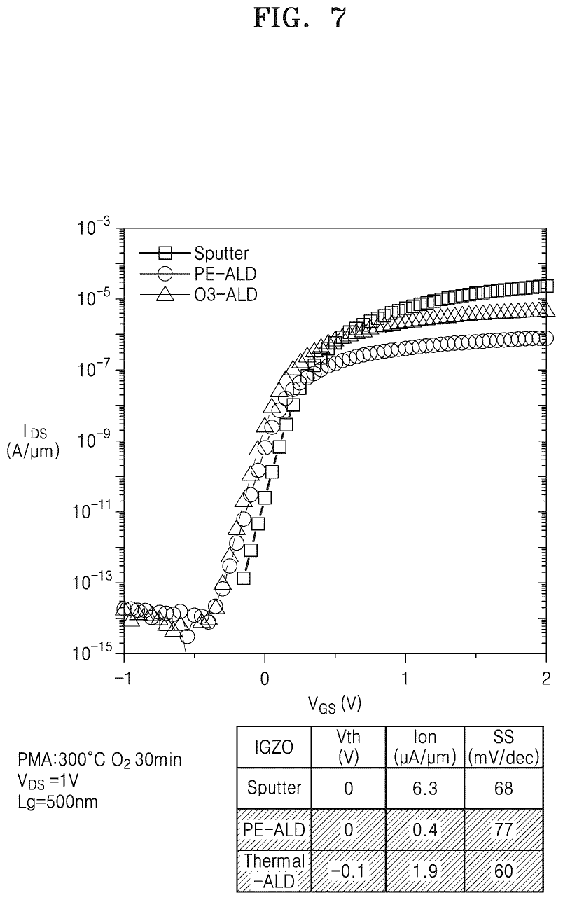

FIG. 7 is an on-current graph for comparing contact characteristics according to a channel-layer stack structure in a bottom-contact oxide semiconductor transistor including a metal electrode arranged under a channel layer.

In the bottom-contact structure, when an oxide semiconductor layer is deposited according to a sputtering method, an on-current may be about 6.3 uA/um, when the oxide semiconductor layer is deposited according to a thermal ALD method, the on-current may be about 1.9 uA/um, and when the oxide semiconductor layer is deposited according to a PEALD method, the on-current may be about 0.4 uA/um.

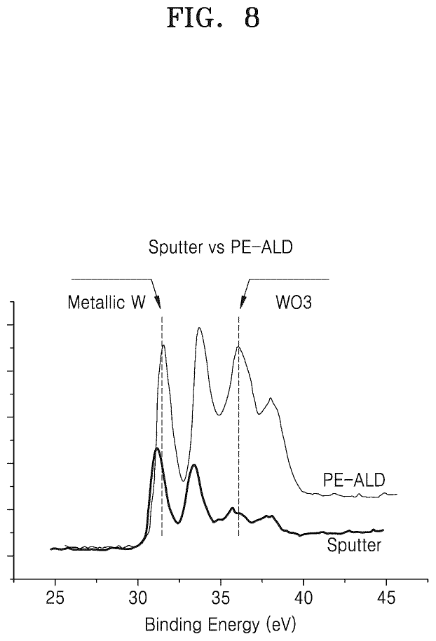

FIG. 8 is a graph showing contact characteristics according to a channel-layer stack structure in a bottom-contact oxide semiconductor transistor including a metal electrode arranged under a channel layer.

Compared to a case where the oxide semiconductor layer is deposited according to the sputtering method with a case when the oxide semiconductor layer is deposited according to the PEALD method, a ratio at which a tungsten electrode is oxidized into tungsten oxide is higher.

The reason the on-current decreases when the channel layer is deposited according to the ALD method in the bottom-contact structure may be that the contact characteristics deteriorate because of an increase in metal oxide on the metal electrode.

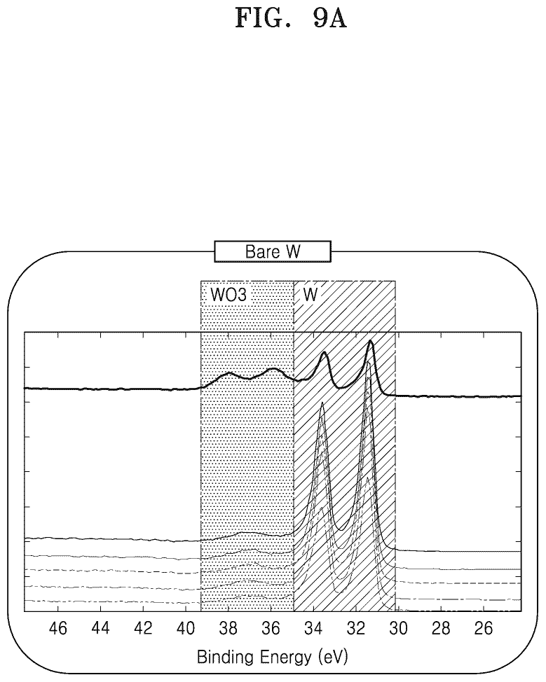

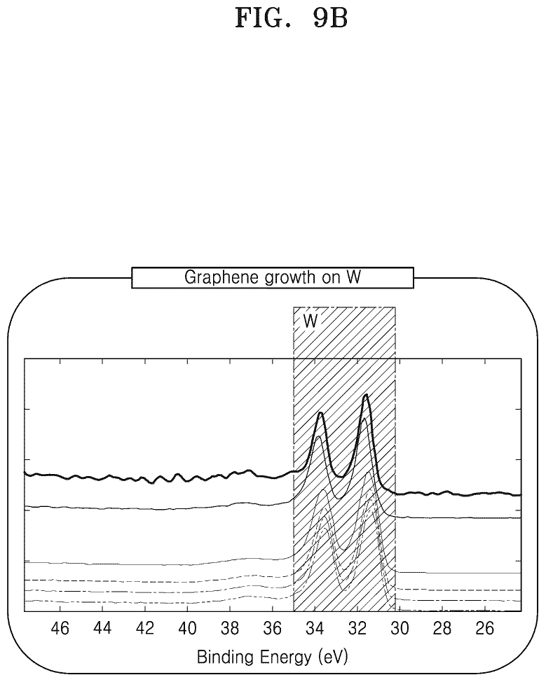

FIGS. 9A and 9B are graphs showing a reduction in metal (tungsten) electrode oxide generation according to the existence of a carbon (graphene) thin film in a bottom-contact oxide semiconductor transistor in which a metal electrode is arranged under a channel layer. FIG. 9A is a graph showing a case where an oxide semiconductor layer is deposited on a tungsten metal electrode according to the PEALD method, and FIG. 9B is a graph showing a case where a graphene layer is deposited on a tungsten metal electrode and an oxide semiconductor layer is deposited on the graphene layer according to the PEALD method.

An illustrated x-ray photoelectron spectroscopy XPS experiment was performed with a Spectral analysis (Monochromatic Al—Kα (h=1486.6 eV)). Ahe Survey scan was conducted under the condition of Pass energy: 280 eV (step 1 eV) (6 min for each scan), An HR scan was conducted under the condition of TOA: 45 (normal mode), X-ray: Beam spot 200 um, Pass energy: 55 eV (energy step 0.1 eV), and the Sputter was conducted under the condition of Ar₊ ion sputtering: 500V 1×1 mm2, Sputter time: 30 sec.

Referring to FIGS. 9A and 9B, it may be predicted or shown or illustrated that, when a carbon thin film such as graphene is arranged on a metal electrode in the bottom-contact oxide semiconductor transistor, contact characteristics when the oxide semiconductor layer 4c is deposited according to the ALD method will be improved, compared to when no carbon thin film is located on a metal electrode.

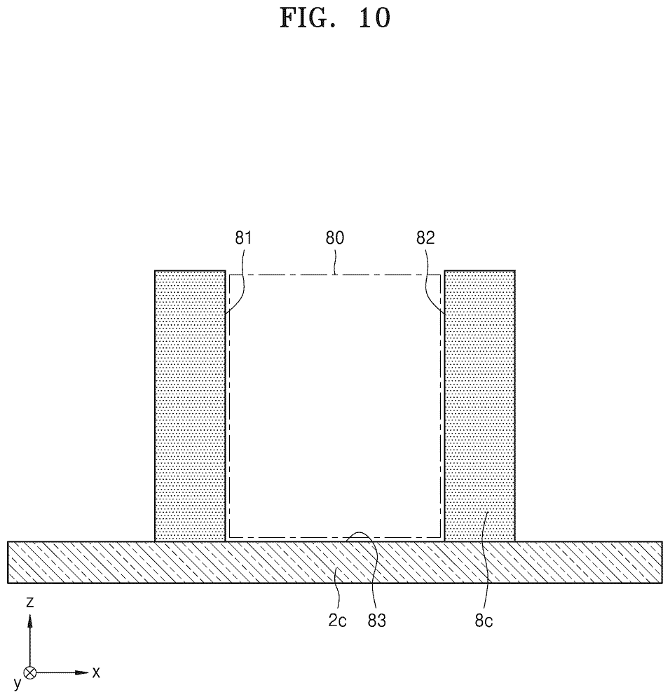

FIG. 10 is a diagram for explaining an operation of stacking a mold insulating layer on a lower electrode in a method of manufacturing a vertical transistor, according to various example embodiments.

A plurality of mold insulating layers 8c extending in the second horizontal direction y may be deposited and patterned on the lower electrode 2c extending in the first horizontal direction x. The mold insulating layers 8c may be stacked when the mold insulating layers 8c have certain heights along the vertical direction z. The mold insulating layers 8c and the lower electrode 2c may form the opening 80.

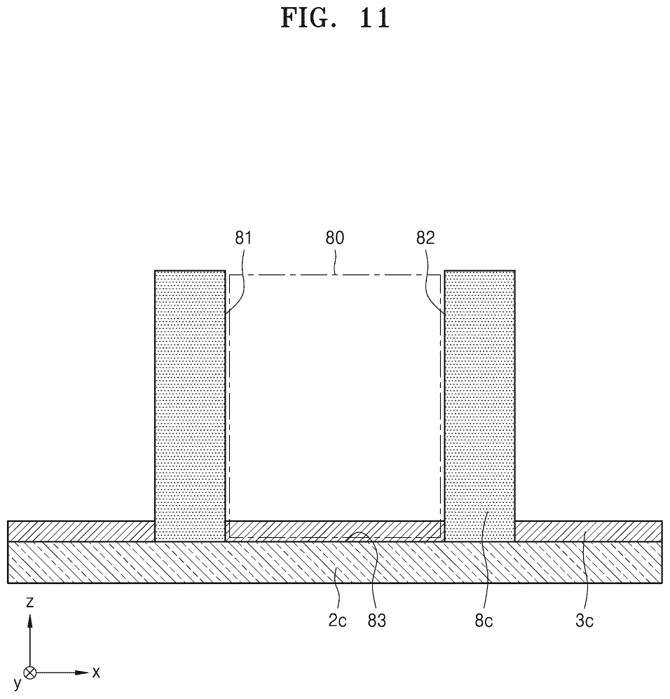

FIG. 11 is a diagram for explaining an operation of stacking a carbon thin film on a lower electrode in a method of manufacturing a vertical transistor, according to various example embodiments.

The carbon thin film 3c may be stacked on the lower electrode 2c. A thickness of the carbon thin film 3c may be about 0.3 nm to about 5 nm. The thickness of the carbon thin film 3c may be about 1 nm to about 2 nm. The carbon thin film 3c may be deposited with various methods of depositing carbon thin films such as graphene films. During the deposition of the carbon thin film 3c, the carbon thin film 3c may be deposited in a non-conformal manner; however, example embodiments are not limited thereto.

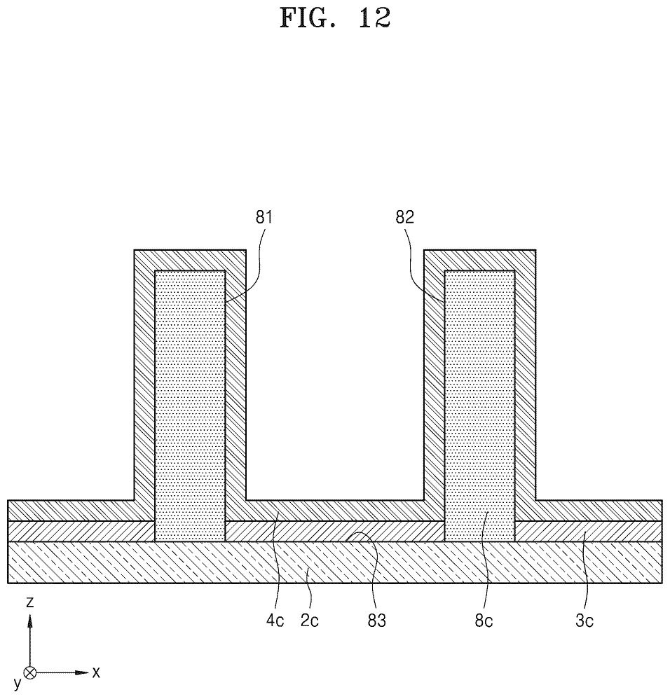

FIG. 12 is a diagram for explaining an operation of stacking an oxide semiconductor layer in a method of manufacturing a vertical transistor, according to various example embodiments.

The oxide semiconductor layer 4c may be deposited according to one or more of a sputtering method, a thermal ALD method, or a PEALD method. The oxide semiconductor layer 4c may be stacked on the carbon thin film 3c and the first sidewall 81 and the second sidewall 82 of the opening at a certain thickness. The oxide semiconductor layer 3c may be deposited in a conformal manner; however, example embodiments are not limited thereto.

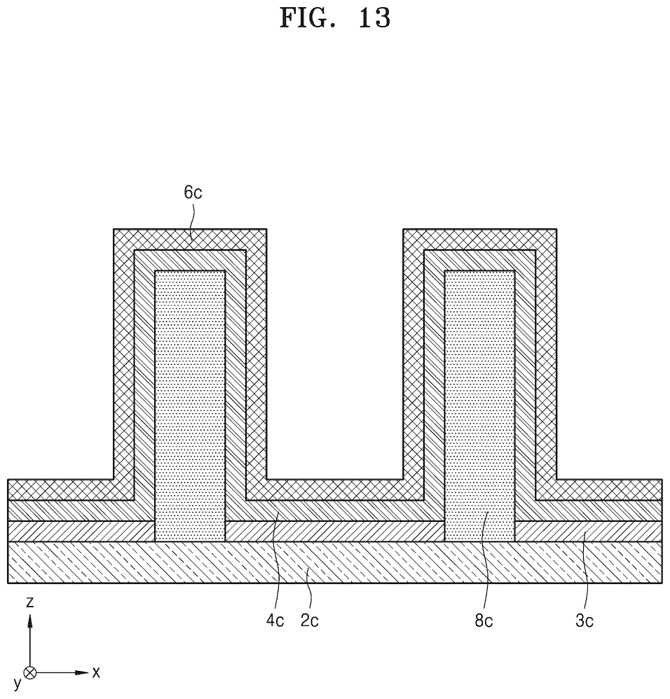

Referring to FIG. 13, the gate insulating layer 6c may be stacked on a surface of the oxide semiconductor layer 4c. The gate insulating layer 6c may be deposited in a conformal manner; however, example embodiments are not limited thereto.

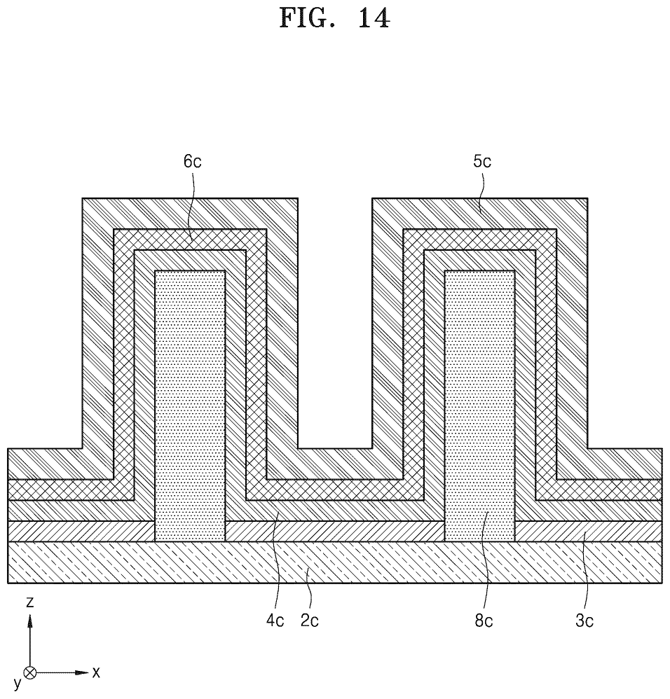

Referring to FIG. 14, the gate electrode 5c may be stacked on a surface of the gate insulating layer 6c. The gate electrode 5c may be deposited in a conformal manner; however, example embodiments are not limited thereto.

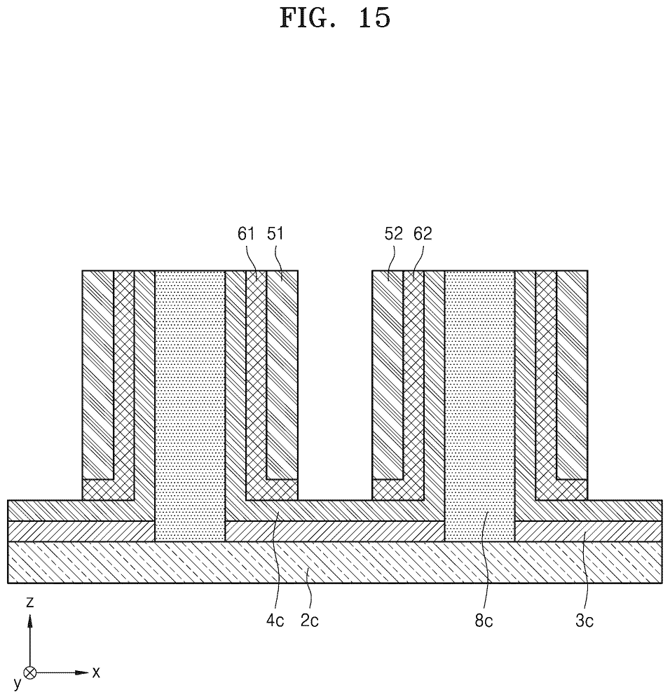

Referring to FIG. 15, etching such as anisotropic etching may be performed from an upper portion of the gate electrode 5c. In a direction towards an upper portion of the mold insulating layer 8c, the gate electrode 5c, the gate insulating layer 6c, and the oxide semiconductor layer 4c are etched, and thus, the upper surface of the mold insulating layer 8c may be exposed. The upper surface of the mold insulating layer 8c, upper surfaces of the first vertical extension 41 and the second vertical extension 42, upper surfaces of the first gate electrode 51 and the second gate electrode 52, and upper surfaces of the first gate insulating layer 61 and the second gate insulating layer 62 may be located at the same level. When the gate electrode 5c is etched once again, the levels of the upper surfaces of the first gate insulating layer 61 and the second gate insulating layer 62 may be lower than the levels of the upper surfaces of the mold insulating layer 8c, the first vertical extension 41, the second vertical extension 42, the first gate electrode 51, and the second gate electrode 52.

The gate electrode 5c and the gate insulating layer 6c are etched in a direction towards the bottom portion of the opening, an upper surface of the lower portion 43 of the oxide semiconductor layer 4c may be partially exposed.

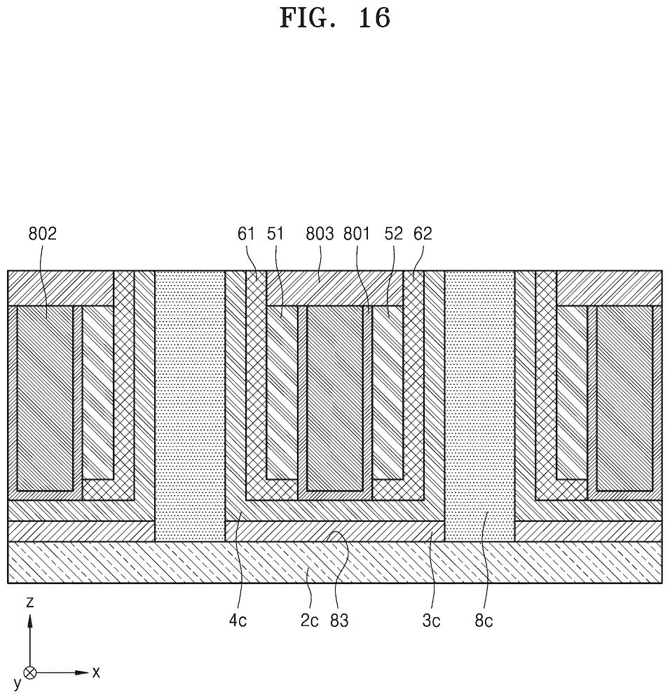

FIG. 16 is a diagram for explaining an operation of forming an insulating liner, a buried insulating layer, and an upper insulating layer in a method of manufacturing a vertical transistor, according to various example embodiments.

The insulating liner 801 may be deposited from a surface of the lower portion of the oxide semiconductor layer 4c and stacked to the level of the upper surface of the gate electrode 5c. The upper insulating layer 803 may be deposited on the upper surface of the gate electrode 5c and the upper surface of the insulating liner 801. The insulating liner 801 may not be distinguished from the buried insulating layer 802. A surface level of the upper insulating layer 803 may be the same as the levels of the upper surface of the mold insulating layer 8c, the upper surfaces of the first vertical extension 41 and the second vertical extension 42, the upper surfaces of the first gate electrode 51 and the second gate electrode 52, and the upper surfaces of the first gate insulating layer 61 and the second gate insulating layer 62.

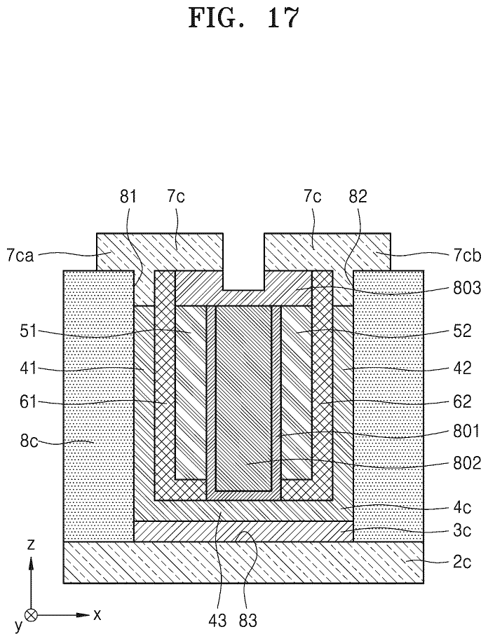

Referring to FIG. 17, upper portions of the first vertical extension 41 and the second vertical extension 42 of the oxide semiconductor layer 4c may partially be etched, and the upper electrode 7c may be deposited on the upper portions of the first vertical extension 41 and the second vertical extension 42. After the upper electrode 7c is deposited, a central portion of the upper electrode 7c and an upper portion of the upper insulating layer 803 may be partially etched.

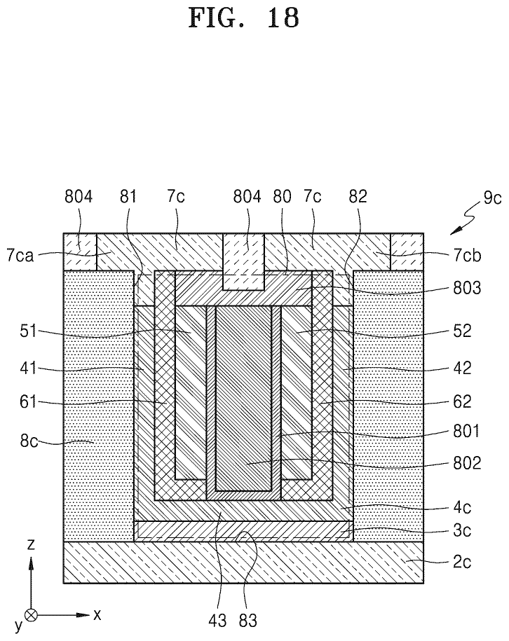

Referring to FIG. 18, the upper electrode insulating layer 804 may cover a space between the upper electrodes 7c and part of the upper portion of the upper insulating layer 803. The level of the upper surface of the upper electrode insulating layer 804 may be the same as the surface level of the upper electrode 7c.

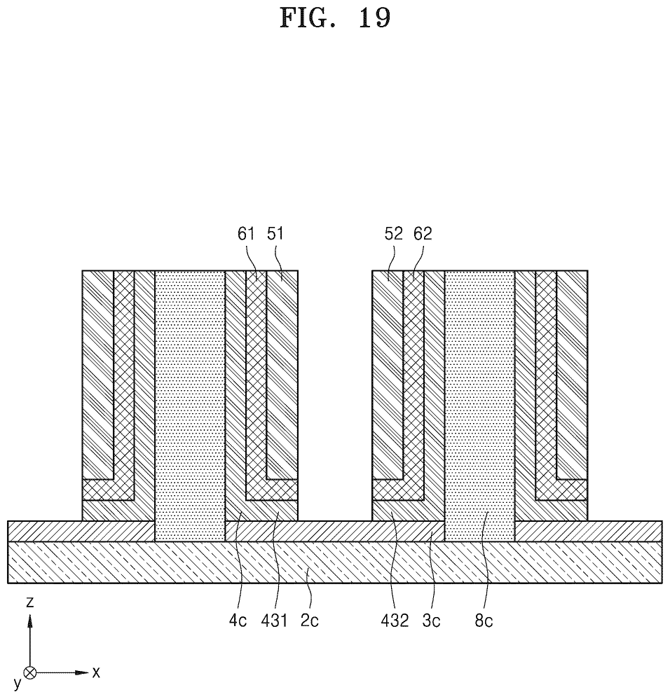

FIG. 19 is a diagram for explaining an etching operation in a method of manufacturing a vertical transistor, according to various example embodiments.

Hereinafter, the repeated descriptions are omitted, and differences are mainly described.

The gate electrode 5c, the gate insulating layer 6c, and the lower portion 43 of the oxide semiconductor layer 4c are partially etched in a direction towards a bottom portion of an opening, and thus, a surface of the carbon thin film 3c may be exposed.

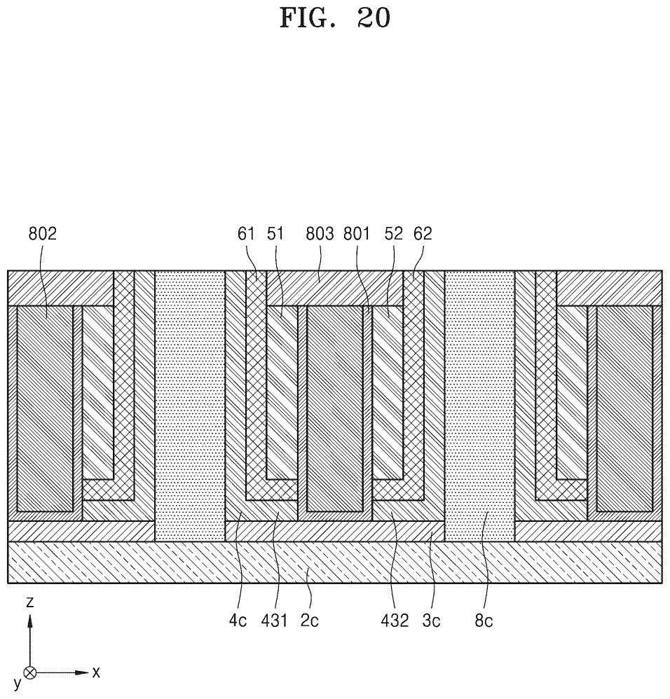

Referring to FIG. 20, the insulating liner 801 may be deposited from the upper surface of the carbon thin film 3c and stacked to the level the upper surface of the gate electrode 5c.

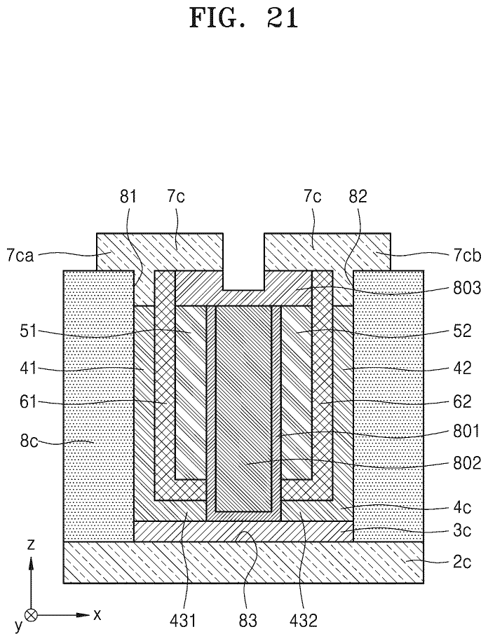

FIG. 21 is a diagram for explaining an operation of forming an upper electrode in a method of manufacturing a vertical transistor, according to various example embodiments.

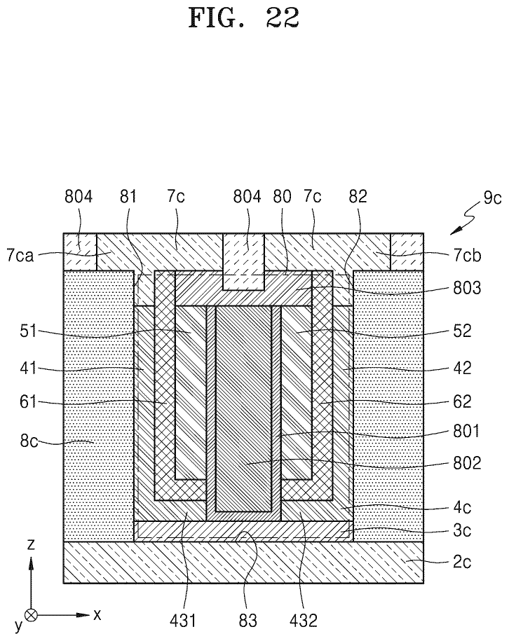

FIG. 22 is a diagram for explaining an operation of forming an upper electrode insulating layer in a method of manufacturing a vertical transistor, according to various example embodiments.

An oxide semiconductor transistor according to the one or more embodiments may have improved contact characteristics regarding contact between electrodes and channel layers. According to a method of manufacturing an oxide semiconductor transistor according to the one or more example embodiments, a transistor having improved contact characteristics may be manufactured.

It should be understood that various example embodiments described herein should be considered in a descriptive sense only and not for purposes of limitation. Descriptions of features or aspects within each example embodiment should typically be considered as available for other similar features or aspects in other embodiments, and further that example embodiments are not necessarily mutually exclusive with one another. While one or more embodiments have been described with reference to the figures, it will be understood by those of ordinary skill in the art that various changes in form and details may be made therein without departing from the spirit and scope as defined by the following claims.

1. A vertical transistor comprising:
a substrate;
a lower electrode on the substrate and comprising a metal material;
a carbon thin film that is conductive and is on the lower electrode;
an oxide semiconductor layer on the carbon thin film;
a gate electrode apart from the oxide semiconductor layer;
a gate insulating layer between the oxide semiconductor layer and the gate electrode; and
an upper electrode arranged on the oxide semiconductor layer,
wherein the lower electrode, the carbon thin film, the oxide semiconductor layer, and the upper electrode are arranged in a direction perpendicular to the substrate.

2. The vertical transistor of claim 1, wherein the gate insulating layer entirely surrounds side surfaces of the oxide semiconductor layer.

3. The vertical transistor of claim 1, wherein the lower electrode, the carbon thin film, the oxide semiconductor layer, and the upper electrode are sequentially stacked without any intervening layer.

4. The vertical transistor of claim 1, wherein the lower electrode has a width greater than or equal to a width of the oxide semiconductor layer.

5. The vertical transistor of claim 1, further comprising:
a mold insulating layer on the lower electrode and defining an opening,
wherein the carbon thin film is on a bottom portion of the opening.

6. The vertical transistor of claim 5, wherein the oxide semiconductor layer comprises a first vertical extension on a first sidewall of the opening, a second vertical extension on a second sidewall of the opening, and a lower portion connected between the first vertical extension and the second vertical extension.

7. The vertical transistor of claim 6, wherein
the gate electrode extends in a second horizontal direction and comprises a first gate electrode corresponding to the first vertical extension and a second gate electrode corresponding to the second vertical extension, and
the gate insulating layer comprises a first gate insulating layer corresponding to the first gate electrode and a second gate insulating layer corresponding to the second gate electrode.

8. The vertical transistor of claim 6, wherein
the gate electrode comprises a first gate electrode and a second gate electrode that are arranged to face each other and are configured to be driven electrically independently, and
the gate insulating layer comprises a first gate insulating layer corresponding to the first gate electrode and a second gate insulating layer corresponding to the second gate electrode.

9. The vertical transistor of claim 6, wherein the oxide semiconductor layer has a U-shaped structure.

10. The vertical transistor of claim 1, wherein the lower electrode comprises at least one metal selected from among tungsten (W), cobalt (Co), nickel (Ni), iron (Fe), titanium (Ti), molybdenum (Mo), chromium (Cr), zirconium (Zr), hafnium (Hf), niobium (Nb), tantalum (Ta), silver (Ag), gold (Au), aluminum (Al), copper (Cu), stannum (Sn), vanadium (V), ruthenium (Ru), platinum (Pt), zinc (Zn), and magnesium (Mg).

11. The vertical transistor of claim 1, wherein the carbon thin film comprises at least one of graphene, fullerene, and a carbon nanotube.

12. The vertical transistor of claim 1, wherein the oxide semiconductor layer comprises at least one selected from among InGaZnO, ZnO, ZrInZnO, InZnO, ZnO, InGaZnO₄, ZnInO, ZnSnO, In₂O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, TiSrO₃, ZIO, IGO.

13. A method of manufacturing a vertical transistor, the method comprising:
arranging a lower electrode on a substrate;
depositing a carbon thin film on the lower electrode, the carbon thin film being conductive;
depositing an oxide semiconductor layer on the carbon thin film;
depositing a gate insulating layer on the oxide semiconductor layer;
depositing a gate electrode on the gate insulating layer; and
depositing an upper electrode on the oxide semiconductor layer,
wherein the depositing of the oxide semiconductor layer comprises,
adsorbing a precursor onto the carbon thin film, and
enabling a reactor to react with the precursor.

14. The method of claim 13, wherein the lower electrode, the carbon thin film, the oxide semiconductor layer, and the upper electrode are deposited to be arranged in a direction perpendicular to the substrate.

15. The method of claim 13, wherein the gate insulating layer is deposited to entirely surround side surfaces of the oxide semiconductor layer.

16. The method of claim 13, wherein the lower electrode, the carbon thin film, the oxide semiconductor layer, and the upper electrode are sequentially stacked without any intervening layers therebetween.

17. The method of claim 13, wherein the lower electrode has a width greater than or equal to a width of the oxide semiconductor layer.

18. The method of claim 13, wherein the enabling the reactor comprises enabling a reactor activated by plasma.

19. The method of claim 13, wherein the depositing of the oxide semiconductor layer further comprises:
providing a first purge gas before the adsorbing of the precursor onto the carbon thin film and after the enabling of the reactor to react with the precursor; and
providing a second purge gas after the enabling of the reactor to react with the precursor.

20. The method of claim 13, further comprising:
depositing a mold insulating layer on the lower electrode with an opening,
wherein the carbon thin film is on a bottom portion of the opening.

21.-24. (canceled)
